(19) United States
(12) Patent Application Publication
(10) Pub. No.: US 2024/0194396 A1
(43) Pub. Date: Jun. 13, 2024

(54) INDUCTOR COMPONENT

(71) Applicant: Murata Manufacturing Co., Ltd., Kyoto-fu (JP)

(72) Inventors: Shoto KAWAMURA, Nagaokakyo-shi (JP); Yuuichirou YOSHIDA, Nagaokakyo-shi (JP); Kenichi TANI, Nagaokakyo-shi (JP)

(73) Assignee: Murata Manufacturing Co., Ltd., Kyoto-fu (JP)

(21) Appl. No.: 18/534,839

(22) Filed: Dec. 11, 2023

(30) Foreign Application Priority Data
Dec. 12, 2022 (JP) 2022-197928

(51) Int. Cl. H01F 27/29; H01F 17/00

(52) U.S. Cl. CPC H01F 27/292; H01F 17/0013; H01F 2017/0073

(57) ABSTRACT

An inductor component includes an element body, a coil in the element body and spirally wound along an axis, and first and second outer electrodes in the element body and electrically connected to the coil. The axis is parallel to a bottom surface of the element body and intersects the first and second side surfaces of the element body. The coil includes coil wiring layers laminated along the axis and including a first coil wiring layer connected to the first outer electrode. When viewed in a direction of the axis, the first coil wiring layer includes a top surface portion opposed to the top surface of the element body and a connecting portion connected between the first outer electrode and the top surface portion, and the connecting portion includes at least one curved portion.

### CROSS-REFERENCE TO RELATED APPLICATION

This application claims benefit of priority to Japanese Patent Application No. 2022-197928, filed Dec. 12, 2022, the entire content of which is incorporated herein by reference.

### BACKGROUND

### Technical Field

The present disclosure relates to an inductor component.

### Background Art

An inductor component in the related art is disclosed in, for example, U.S. Pat. No. 10,923,259. The inductor component includes an element body, a coil provided in the element body and spirally wound along an axis, and a first outer electrode and a second outer electrode provided on the element body and electrically connected to the coil. The coil includes a plurality of coil wiring layers laminated along the axis, and the plurality of coil wiring layers include a first coil wiring layer connected to the first outer electrode. When viewed in the axial direction, the first coil wiring layer includes a top surface portion opposed to a top surface of the element body and a connecting portion connected between the first outer electrode and the top surface portion, and the connecting portion is formed in a linear shape.

### SUMMARY

In recent years, efforts have been made to reduce the size of inductor components and to increase the thickness of coil wiring layers in order to improve Q characteristics. It has been found that, in such a situation, the volume ratio of the coil wiring layer in the element body increases, and in the inductor component in the related art, the thermal stress applied to the connecting portion of the coil wiring layer at the time of firing or mounting increases due to the difference in thermal expansion coefficient between the element body and the coil wiring layer. In addition, it has been found that since the thermal stress applied to the connecting portion increases, the stress at the boundary portion between the connecting portion and the outer electrode increases.

Accordingly, the present disclosure provides an inductor component capable of reducing stress at a boundary portion between a coil wiring layer and an outer electrode.

An inductor component according to an aspect of the present disclosure includes an element body; a coil provided in the element body and spirally wound along an axis; and a first outer electrode and a second outer electrode that are provided in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The axis is parallel to the bottom surface and intersects the first side surface and the second side surface. The coil includes a plurality of coil wiring layers laminated along the axis, and the plurality of coil wiring layers include a first coil wiring layer connected to the first outer electrode. When viewed in a direction of the axis, the first coil wiring layer includes a top surface portion opposed to the top surface and a connecting portion connected between the first outer electrode and the top surface portion, and the connecting portion includes at least one curved portion.

According to the aspect, since the connecting portion includes the curved portion, even when thermal stress is applied to the inductor component at the time of firing or mounting, the stress applied to the connecting portion can be reduced. In addition, even when bending stress is applied to the inductor component at the time of mounting, the stress applied to the connecting portion can be reduced. Thus, stress at the boundary portion between the connecting portion and the outer electrode can be reduced.

An inductor component according to an aspect of the present disclosure includes an element body; a coil provided in the element body and spirally wound along an axis; and a first outer electrode and a second outer electrode that are provided in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The axis is parallel to the bottom surface and intersects the first side surface and the second side surface. The coil includes a plurality of coil wiring layers laminated along the axis, and the plurality of coil wiring layers include a second coil wiring layer connected to the second outer electrode. When viewed in a direction of the axis, the second coil wiring layer includes a first outer electrode opposing portion opposed to the first outer electrode, and a connecting portion connected between the second outer electrode and the first outer electrode opposing portion and opposed to the bottom surface, and the connecting portion includes at least one curved portion.

According to the aspect, since the connecting portion includes the curved portion, even when thermal stress is applied to the inductor component at the time of firing or mounting, the stress applied to the connecting portion can be reduced. In addition, even when bending stress is applied to the inductor component at the time of mounting, the stress applied to the connecting portion can be reduced. Thus, stress at the boundary portion between the connecting portion and the outer electrode can be reduced.

According to the inductor component of one aspect of the present disclosure, stress at the boundary portion between the coil wiring layer and the outer electrode can be reduced.

### BRIEF DESCRIPTION OF THE DRAWINGS

FIG. 1 is a perspective view illustrating a first embodiment of an inductor component;

FIG. 2 is a perspective front view of the inductor component as viewed from a first side surface side;

FIG. 3 is an exploded plan view of the inductor component;

FIG. 4 is a front view of a first coil wiring layer when viewed in the axial direction;

FIG. 5 is a front view of a second coil wiring layer when viewed in the axial direction;

FIG. 6 is a front view illustrating a second embodiment of the inductor component when viewed in the axial direction of the first coil wiring layer;

FIG. 7 is a front view illustrating a third embodiment of the inductor component when viewed in the axial direction of the first coil wiring layer; and

FIG. 8 is a front view illustrating a fourth embodiment of the inductor component when viewed in the axial direction of the second coil wiring layer.

### DETAILED DESCRIPTION

Hereinafter, an inductor component according to an aspect of the present disclosure will be described in detail with reference to the illustrated embodiments. Note that some of the drawings are schematic and do not necessarily reflect actual dimensions or ratios.

### First Embodiment

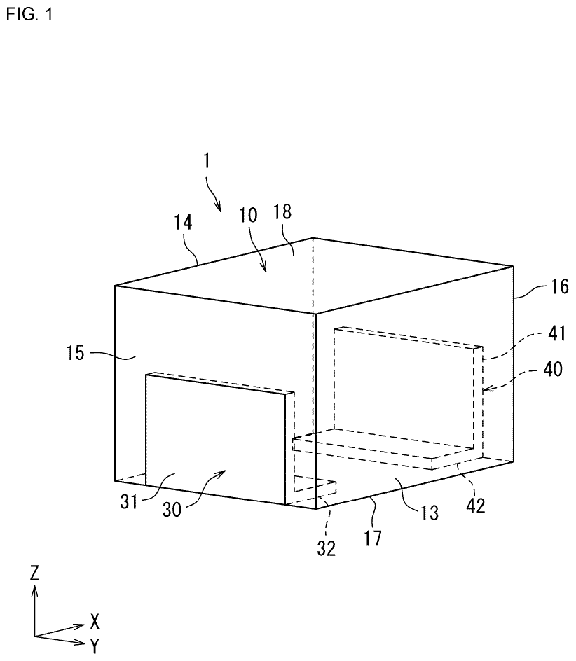

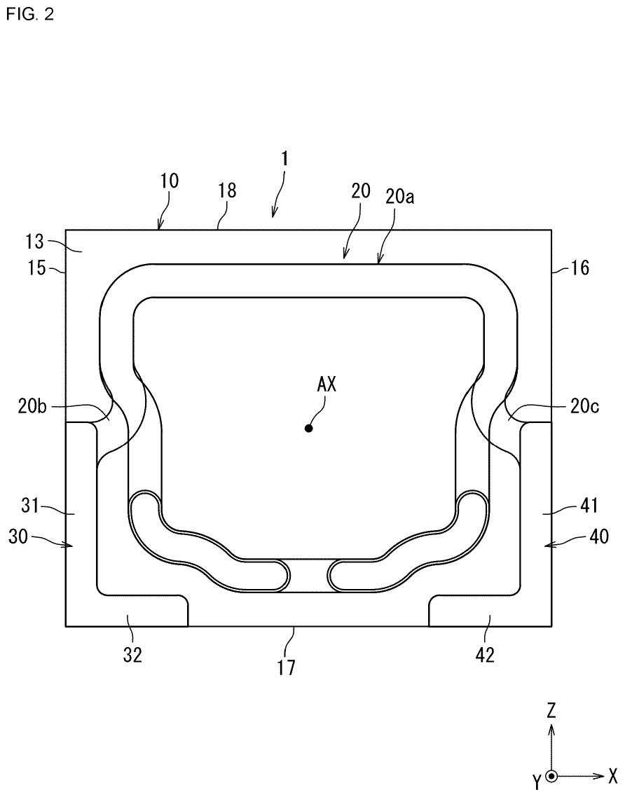

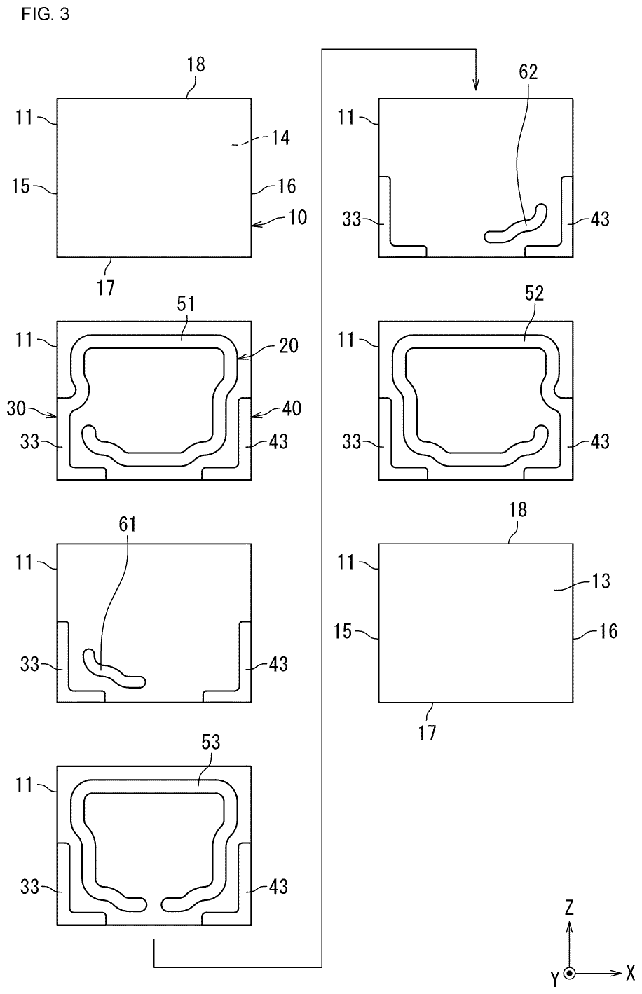

FIG. 1 is a perspective view illustrating a first embodiment of an inductor component. FIG. 2 is a perspective front view of the inductor component as viewed from a first side surface side. FIG. 3 is an exploded plan view of the inductor component. As illustrated in FIGS. 1, 2, and 3, an inductor component 1 includes an element body 10, a coil 20 provided in the element body 10 and spirally wound along an axis AX, and a first outer electrode 30 and a second outer electrode 40 provided in the element body 10 and electrically connected to the coil 20. For the sake of convenience, the element body and the coil are depicted as transparent in FIG. 2 such that the structure can be easily understood, but may be translucent or opaque.

The inductor component 1 is electrically connected to wiring of a circuit board (not illustrated) with the first and second outer electrodes 30 and 40 interposed therebetween. The inductor component 1 is used as, for example, an impedance matching coil (matching coil) of a radio-frequency circuit, and is used in electronic devices such as a personal computer, a DVD player, a digital camera, a TV, a mobile phone, car electronics, and medical or industrial machines. However, the use of the inductor component 1 is not limited thereto, and for example, the inductor component 1 can also be used in a tuning circuit, a filter circuit, a rectifying and smoothing circuit, or the like.

The element body 10 is formed in a substantially rectangular parallelepiped shape. A surface of the element body 10 includes a first end surface 15 and a second end surface 16 opposed to each other, a first side surface 13 and a second side surface 14 opposed to each other, a bottom surface 17 connected between the first end surface 15 and the second end surface 16 and between the first side surface 13 and the second side surface 14, and a top surface 18 opposed to the bottom surface 17. The bottom surface 17 is a surface that is opposed to a mounting substrate (not illustrated) side when the inductor component 1 is mounted on the mounting substrate.

As illustrated, the X direction is orthogonal to the first end surface 15 and the second end surface 16, and is a direction from the first end surface 15 toward the second end surface 16. The Y direction is orthogonal to the first side surface 13 and the second side surface 14, and is a direction from the second side surface 14 toward the first side surface 13. The Z direction is orthogonal to the bottom surface 17 and the top surface 18, and is a direction from the bottom surface 17 toward the top surface 18. The X direction is also referred to as a length direction of the element body 10, the Y direction is also referred to as a width direction of the element body 10, and the Z direction is also referred to as a height direction of the element body 10. The X direction, the Y direction, and the Z direction are directions orthogonal to each other, and constitute a left-handed system when arranged in the order of X, Y, and Z.

The element body 10 is formed by laminating a plurality of insulating layers 11. The insulating layers 11 are made of, for example, a material containing borosilicate glass as a main component or a material such as ferrite or resin. The laminating direction of the insulating layers 11 is a direction (Y direction) parallel to the first and second end surfaces 15 and 16 and the bottom surface 17 of the element body 10. That is, the insulating layers 11 has a layered shape extending in the XZ plane. Term “parallel” in the present application is not limited to a strict parallel relationship, and includes a substantially parallel relationship in consideration of a practical range of variation. In the element body 10, the interfaces between the plurality of insulating layers 11 are not clear due to firing or the like in some cases. In FIG. 3, a direction from top to bottom is defined as the laminating direction (Y direction).

The first outer electrode 30 and the second outer electrode 40 are made of, for example, a conductive material such as Ag, Cu, Au, or an alloy containing any of these metals as a main component. The first outer electrode 30 has an L shape extending from the first end surface 15 to the bottom surface 17. The first outer electrode 30 is embedded in the element body 10 so as to be exposed from the first end surface 15 and the bottom surface 17. The first outer electrode 30 includes a first end surface portion 31 extending along the first end surface 15, and a first bottom surface portion 32 connected to the first end surface portion 31 and extending along the bottom surface 17.

The second outer electrode 40 has an L shape extending from the second end surface 16 to the bottom surface 17. The second outer electrode 40 is embedded in the element body 10 so as to be exposed from the second end surface 16 and the bottom surface 17. The second outer electrode 40 includes a second end surface portion 41 extending along the second end surface 16, and a second bottom surface portion 42 connected to the second end surface portion 41 and extending along the bottom surface 17.

The first outer electrode 30 has a configuration in which a plurality of first outer electrode conductor layers 33 embedded in the element body 10 (insulating layers 11) are laminated. The second outer electrode 40 has a configuration in which a plurality of second outer electrode conductor layers 43 embedded in the element body 10 (insulating layers 11) are laminated. The first outer electrode conductor layer 33 extends along the first end surface 15 and the bottom surface 17, and the second outer electrode conductor layer 43 extends along the second end surface 16 and the bottom surface 17.

Thus, since the first and second outer electrodes 30 and 40 and can be embedded in the element body 10, the inductor component can be reduced in size as compared with a configuration in which outer electrodes are externally attached to the element body 10. In addition, the coil 20 and the outer electrodes 30 and 40 can be formed in the same process, and by reducing variations in the positional relationship between the coil 20 and the outer electrodes 30 and 40, variations in the electrical characteristics of the inductor component 1 can be reduced.

As illustrated in FIG. 2, the coil 20 is made of, for example, the conductive material same as the first and second outer electrodes 30 and 40. The coil 20 is spirally wound along the laminating direction of the insulating layers 11. A first end of the coil 20 is connected to the first outer electrode 30, and a second end of the coil 20 is connected to the second outer electrode 40. In the present embodiment, the coil 20 and the first and second outer electrodes 30 and 40 are integrated with each other, and there is no clear boundary therebetween. However, the present embodiment is not limited thereto, and the coil and the outer electrodes may be formed of different materials or by different methods to have a boundary therebetween.

The coil 20 is wound along the axis AX such that the axis AX is parallel to the bottom surface 17 and intersects the first side surface 13 and the second side surface 14. The axis AX of the coil 20 coincides with the laminating direction (Y direction) of the insulating layer 11. The axis AX of the coil 20 means the central axis of the spiral shape of the coil 20.

The coil 20 includes a winding portion 20a, a first extended portion 20b connected between a first end of the winding portion 20a and the first outer electrode 30, and a second extended portion 20c connected between a second end of the winding portion 20a and the second outer electrode 40. In the present embodiment, the winding portion 20a and the first and second extended portions 20b and 20c are integrated, and there is no clear boundary therebetween. However, the present embodiment is not limited thereto, and the winding portion and the extended portions may be formed of different materials or by different methods so that there is a boundary therebetween.

The winding portion 20a is spirally wound along the axis AX. That is, the winding portion 20a refers to a spirally wound portion where the coil 20 overlaps itself when viewed in the direction parallel to the axis AX. The first and second extended portions 20b and 20c refer to portions out of the overlapping portion.

When viewed in the axis AX direction of the coil 20, the shape of the coil 20 is bilaterally symmetrical with respect to a straight line that passes through the axis AX of the coil 20 and is parallel to the Z direction. As a result, variations in the characteristics of the inductor component 1 can be suppressed.

As illustrated in FIG. 3, the coil 20 includes a plurality of coil wiring layers 51 to 53 laminated along the axis AX, and a plurality of via wiring layers 61 and 62 located between the coil wiring layers adjacent to each other in the axis AX direction and connecting the coil wiring layers adjacent to each other in the axis AX direction. Each of the plurality of coil wiring layers 51 to 53 is provided in the insulating layer 11, and each of the plurality of via wiring layers 61 and 62 is provided in the insulating layer 11.

Each of the plurality of coil wiring layers 51 to 53 is wound on a plane and forms a spiral while being electrically connected in series. Each of the plurality of coil wiring layers 51 to 53 is formed by being wound on the main surface (XZ plane) of the insulating layer 11 orthogonal to the axis AX direction (Y direction). The number of turns of each of the coil wiring layers 51 to 53 is less than one, but may be one or more.

The via wiring layers 61 and 62 penetrate through the insulating layers 11 in the thickness direction (Y direction). The coil wiring layers adjacent to each other in the laminating direction are electrically connected in series through the via wiring layer. In this way, the plurality of coil wiring layers 51 to 53 constitute a spiral while being electrically connected to each other in series.

Specifically, a first coil wiring layer 51, a third coil wiring layer 53, and a second coil wiring layer 52 are sequentially laminated along the Y direction. An end portion of the first coil wiring layer 51 is connected to the first outer electrode conductor layer 33 of the first outer electrode 30. An end portion of the second coil wiring layer 52 is connected to the second outer electrode conductor layer 43 of the second outer electrode 40.

The first via wiring layer 61 is positioned between the first coil wiring layer 51 and the third coil wiring layer 53 and connects an end portion of the first coil wiring layer 51 and an end portion of the third coil wiring layer 53. The second via wiring layer 62 is positioned between the third coil wiring layer 53 and the second coil wiring layer 52 and connects an end portion of the third coil wiring layer 53 and an end portion of the second coil wiring layer 52.

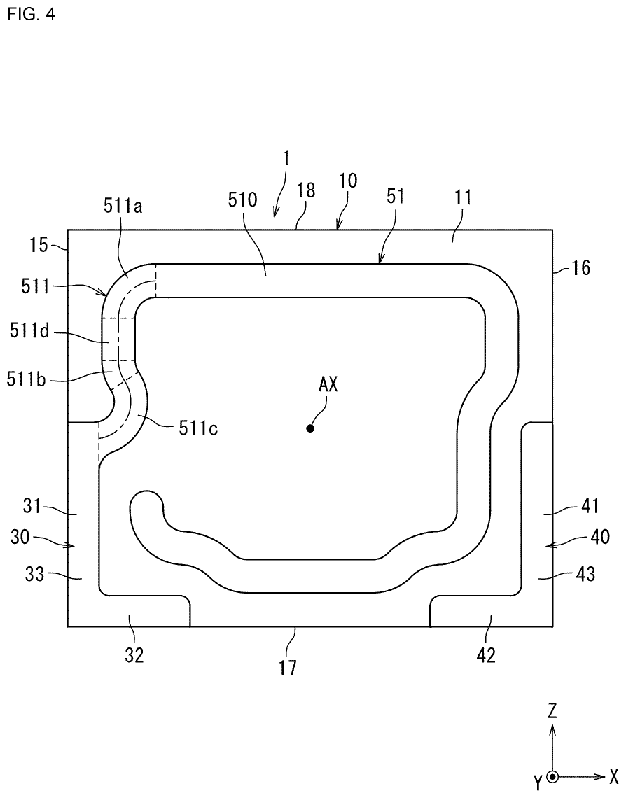

FIG. 4 is a front view of the first coil wiring layer 51 when viewed in the axis AX direction. As illustrated in FIG. 4, when viewed in the axis AX direction, the first coil wiring layer 51 is connected to the first end surface portion 31 of the first outer electrode 30. The first coil wiring layer 51 includes a top surface portion 510 opposed to the top surface 18 and a connecting portion 511 connected between the first outer electrode 30 (first end surface portion 31) and the top surface portion 510. The connecting portion 511 includes at least one curved portion 511a, 511b, or 511c. The curved portion corresponds to, for example, an arc.

According to the above-described configuration, since the connecting portion 511 includes the curved portions 511a, 511b, and 511c, even when thermal stress is applied to the inductor component 1 at the time of firing or mounting, the stress applied to the connecting portion 511 can be reduced. In addition, even when bending stress is applied to the inductor component 1 at the time of mounting, the stress applied to the connecting portion 511 can be reduced. Thus, stress at the boundary portion between the connecting portion 511 and the first outer electrode 30 can be reduced. For example, the occurrence of cracks in the boundary portion between the connecting portion 511 and the first outer electrode 30 can be suppressed.

As illustrated in FIG. 4, when viewed in the axis AX direction, the top surface portion 510 includes a linear portion parallel to the top surface 18. In this embodiment, the top surface portion 510 is formed in a linear shape including only a linear portion. Thus, the top surface portion 510 can be easily manufactured, and variations in the inductor component 1 can be suppressed.

When viewed in the axis AX direction, the connecting portion 511 includes a first curved portion 511a protruding outward in the radial direction of the coil 20, a linear portion 511d parallel to the first end surface 15, a second curved portion 511b protruding outward in the radial direction of the coil 20, and a third curved portion 511c protruding inward in the radial direction of the coil 20, in this order from the top surface portion 510 toward the first outer electrode 30. The first curved portion 511a is connected to the top surface portion 510. The third curved portion 511c is connected to the first end surface portion 31 of the first outer electrode 30. The boundaries between the first curved portion 511a, the second curved portion 511b, the third curved portion 511c, and the linear portion 511d are indicated by dotted lines in FIG. 4. According to the above-described configuration, since the connecting portion 511 includes the first curved portion 511a, the second curved portion 511b, and the third curved portion 511c, even when thermal stress or bending stress is applied to the inductor component 1 at the time of mounting or the like, stress applied to the connecting portion 511 can be reduced. The number of the curved portions 511a, 511b, and 511c and the linear portions 511d may be increased or decreased.

As illustrated in FIG. 4, preferably, the total length of the linear portions 511d is 40% or less of the total length of the curved portions 511a, 511b, and 511c. Here, the lengths of the linear portion 511d and the curved portions 511a, 511b, and 511c each refer to the size in the extending direction of the center line of the connecting portion 511. The center line is indicated by the dash-dot line in FIG. 4. According to the above-described configuration, even when thermal stress or bending stress is applied to the inductor component 1, the stress applied to the connecting portion 511 can be further reduced because the ratio of the linear portion 511d is small. Thus, stress at the boundary portion between the connecting portion 511 and the first outer electrode 30 can be further reduced.

As illustrated in FIG. 4, the first curved portion 511a connected to the top surface portion 510 protrudes outward in the radial direction of the coil when viewed in the axis AX direction. According to the above-described configuration, the area of the inner diameter of the coil 20 is increased in the first curved portion 511a connected to the top surface portion 510. That is, the inner diameter of the coil 20 increases at the corner portions of the coil 20. As a result, inductance characteristics and Q characteristics can be improved.

As illustrated in FIG. 4, when viewed in the axis AX direction, the connecting portion 511 includes the linear portion 511d and at least one curved portion between the linear portion 511d and the first outer electrode 30. Specifically, the connecting portion 511 includes the second curved portion 511b and the third curved portion 511c between the linear portion 511d and the first outer electrode 30. Thus, since the curved portion is provided in the vicinity of the first outer electrode 30 to which thermal stress or bending stress is likely to be applied, stress applied to the connecting portion 511 can be further reduced.

Preferably, the linear portion 511d is opposed to the first end surface 15. Thus, since the linear portion 511d is opposed to the first end surface 15, the inner diameter of the coil 20 can be increased, and the inductance can be improved.

Preferably, at least one curved portion between the linear portion 511d and the first outer electrode 30 protrudes inward in the radial direction of the coil 20. Specifically, the third curved portion 511c protrudes inward in the radial direction of the coil 20. Thus, since the third curved portion 511c is separated from the first end surface 15, stress applied to the connecting portion 511 can be further reduced.

Preferably, at least one curved portion between the linear portion 511d and the first outer electrode 30 is directly connected to the first outer electrode 30. Specifically, the third curved portion 511c is directly connected to the first outer electrode 30. Thus, since the third curved portion 511c is separated from the first end surface 15, stress applied to the connecting portion 511 can be further reduced.

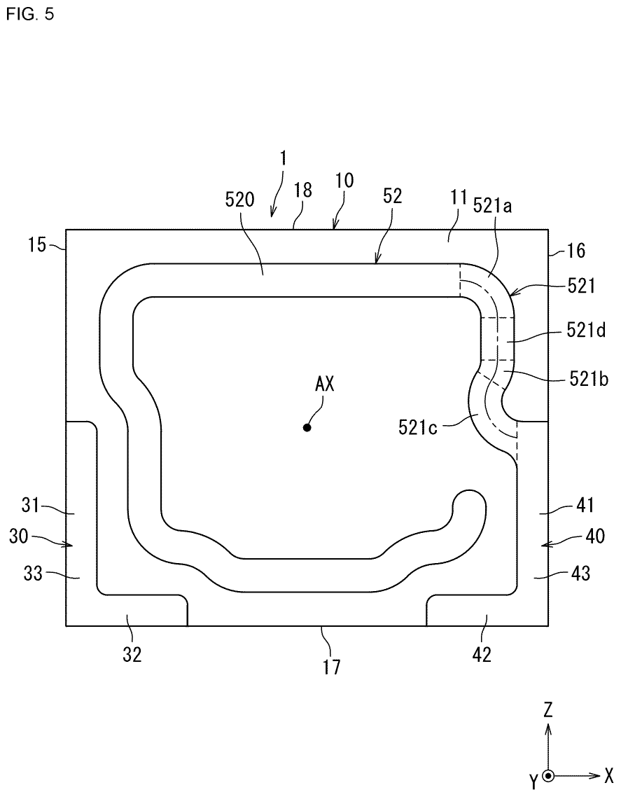

FIG. 5 is a front view of the second coil wiring layer 52 when viewed in the axis AX direction. As illustrated in FIG. 5, when viewed in the axis AX direction, the second coil wiring layer 52 is connected to the second end surface portion 41 of the second outer electrode 40. The second coil wiring layer 52 includes a top surface portion 520 opposed to the top surface 18 and a connecting portion 521 connected between the second outer electrode 40 (second end surface portion 41) and the top surface portion 520. The connecting portion 521 includes at least one curved portion 521a, 521b, or 521c. The curved portion corresponds to, for example, an arc.

According to the above-described configuration, since the connecting portion 521 includes the curved portions 521a, 521b, and 521c, even when thermal stress is applied to the inductor component 1 at the time of firing or mounting, the stress applied to the connecting portion 521 can be reduced. In addition, even when bending stress is applied to the inductor component 1 at the time of mounting, the stress applied to the connecting portion 521 can be reduced. Thus, stress at the boundary portion between the connecting portion 521 and the second outer electrode 40 can be reduced. For example, the occurrence of cracks in the boundary portion between the connecting portion 521 and the second outer electrode 40 can be suppressed.

As illustrated in FIG. 5, when viewed in the axis AX direction, the top surface portion 520 includes a linear portion parallel to the top surface 18. In this embodiment, the top surface portion 520 is formed in a linear shape including only a linear portion. Thus, the top surface portion 520 can be easily manufactured, and variations in the inductor component 1 can be suppressed.

When viewed in the axis AX direction, the connecting portion 521 includes a first curved portion 521a protruding outward in the radial direction of the coil 20, a linear portion 521d parallel to the first end surface 15, a second curved portion 521b protruding outward in the radial direction of the coil 20, and a third curved portion 521c protruding inward in the radial direction of the coil 20, in this order from the top surface portion 520 toward the second outer electrode 40. The first curved portion 521a is connected to the top surface portion 520. The third curved portion 521c is connected to the second end surface portion 41 of the second outer electrode 40. The boundaries between the first curved portion 521a, the second curved portion 521b, the third curved portion 521c, and the linear portion 521d are indicated by dotted lines in FIG. 5. According to the above-described configuration, since the connecting portion 521 includes the first curved portion 521a, the second curved portion 521b, and the third curved portion 521c, even when thermal stress or bending stress is applied to the inductor component 1 at the time of mounting or the like, stress applied to the connecting portion 521 can be reduced. The number of the curved portions 521a, 521b, and 521c and the linear portions 521d may be increased or decreased.

As illustrated in FIG. 5, preferably, the total length of the linear portions 521d is 40% or less of the total length of the curved portions 521a, 521b, and 521c. Here, the lengths of the linear portion 521d and the curved portions 521a, 521b, and 521c each refer to the size in the extending direction of the center line of the connecting portion 521. The center line is indicated by the dash-dot line in FIG. 5. According to the above-described configuration, even when thermal stress or bending stress is applied to the inductor component 1, the stress applied to the connecting portion 521 can be further reduced because the ratio of the linear portion 521d is small. Thus, stress at the boundary portion between the connecting portion 521 and the second outer electrode 40 can be further reduced.

As illustrated in FIG. 5, the first curved portion 521a connected to the top surface portion 520 protrudes outward in the radial direction of the coil when viewed in the axis AX direction. According to the above-described configuration, the area of the inner diameter of the coil 20 is increased in the first curved portion 521a connected to the top surface portion 520. That is, the inner diameter of the coil 20 increases at the corner portions of the coil 20. As a result, inductance characteristics and Q characteristics can be improved.

As illustrated in FIG. 5, when viewed in the axis AX direction, the connecting portion 521 includes the linear portion 521d and at least one curved portion between the linear portion 521d and the second outer electrode 40. Specifically, the connecting portion 521 includes the second curved portion 521b and the third curved portion 521c between the linear portion 521d and the second outer electrode 40. Thus, since the curved portion is provided in the vicinity of the second outer electrode 40 to which thermal stress or bending stress is likely to be applied, stress applied to the connecting portion 521 can be further reduced.

Preferably, the linear portion 521d is opposed to the second end surface 16. Thus, since the linear portion 521d is opposed to the second end surface 16, the inner diameter of the coil 20 can be increased, and the inductance can be improved.

Preferably, at least one curved portion between the linear portion 521d and the second outer electrode 40 protrudes inward in the radial direction of the coil 20. To be more specific, the third curved portion 521c protrudes inward in the radial direction of the coil 20. Thus, since the third curved portion 521c is separated from the second end surface 16, stress applied to the connecting portion 521 can be further reduced.

Preferably, at least one curved portion between the linear portion 521d and the second outer electrode 40 is directly connected to the second outer electrode 40. Specifically, the third curved portion 521c is directly connected to the second outer electrode 40. Thus, since the third curved portion 521c is separated from the second end surface 16, stress applied to the connecting portion 521 can be further reduced.

Next, a method for manufacturing the inductor component 1 will be described.

As illustrated in FIG. 3, the inductor component 1 is manufactured by alternately laminating the first to third coil wiring layers 51 to 53 and the first and second via wiring layers 61 and 62 together with the insulating layers 11 from top to bottom in the drawing. The coil wiring layers 51 to 53 are provided on the insulating layer 11 by, for example, screen printing. The via wiring layers 61 and 62 are provided at an opening part by, for example, screen-printing after providing the opening part in the insulating layer 11 by, for example, a photolithography method or a laser method.

### Second Embodiment

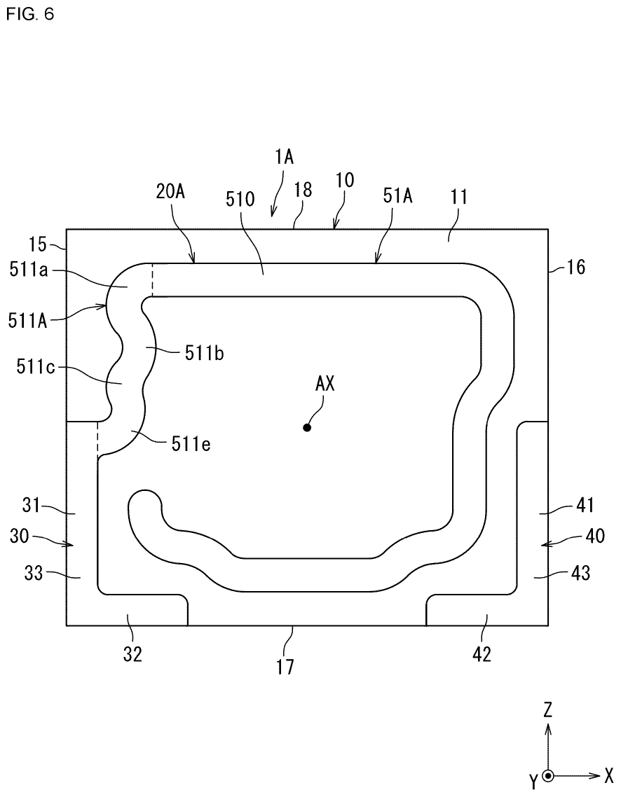

FIG. 6 is a front view illustrating a second embodiment of the inductor component when viewed in the axial direction of the first coil wiring layer. The second embodiment is different from the first embodiment in the shape of the connecting portion of the first coil wiring layer of the coil. This different configuration will be described below. Other configurations are the same as those of the first embodiment, and the reference numerals same as those of the first embodiment are given and the description thereof will be omitted.

As illustrated in FIG. 6, in a coil 20A of an inductor component 1A of the second embodiment, a connecting portion 511A of a first coil wiring layer 51A is formed in a curved shape when viewed in the axis AX direction. Term “curved” means that the shape does not include a linear portion but includes at least one curved portion. According to the above-described configuration, even when thermal stress or bending stress is applied to the inductor component 1A, the stress applied to the connecting portion 511A can be further reduced because the connecting portion 511A does not include a linear portion. Thus, stress at the boundary portion between the connecting portion 511A and the first outer electrode 30 can be further reduced.

Preferably, the connecting portion 511A is composed of at least four curved portions. Specifically, when viewed in the axis AX direction, the connecting portion 511A includes, in order from the top surface portion 510 toward the first outer electrode 30, a first curved portion 511a that protrudes outward in the radial direction of the coil 20A, a second curved portion 511b that protrudes inward in the radial direction of the coil 20A, a third curved portion 511c that protrudes outward in the radial direction of the coil 20A, and a fourth curved portion 511e that protrudes inward in the radial direction of the coil 20A. The first curved portion 511a is connected to the top surface portion 510. The fourth curved portion 511e is connected to the first outer electrode 30.

According to the above-described configuration, since the connecting portion 511A is formed in a meandering shape, even when thermal stress or bending stress is applied to the inductor component 1A, the stress applied to the connecting portion 511A can be further reduced. In addition, the flexibility of the winding method of the coil 20A is increased, and a design with higher Q characteristics can be realized. The number of the curved portions of the connecting portion may be increased.

Although not illustrated, preferably, similarly, the connecting portion 521 (see FIG. 5) of the second coil wiring layer 52 may be formed in a curved shape when viewed in the axis AX direction. According to this configuration, even when thermal stress or bending stress is applied to the inductor component, the stress applied to the connecting portion can be further reduced because the connecting portion does not include a linear portion. Thus, stress at the boundary portion between the connecting portion and the second outer electrode 40 can be further reduced.

Preferably, the connecting portion 521 (see FIG. 5) of the second coil wiring layer 52 may be constituted by at least four curved portions. According to this configuration, since the connecting portion is formed in a meandering shape, even when thermal stress or bending stress is applied to the inductor component, the stress applied to the connecting portion can be further reduced. In addition, the flexibility of the winding method of the coil is increased, and a design with higher Q characteristics can be realized.

### Third Embodiment

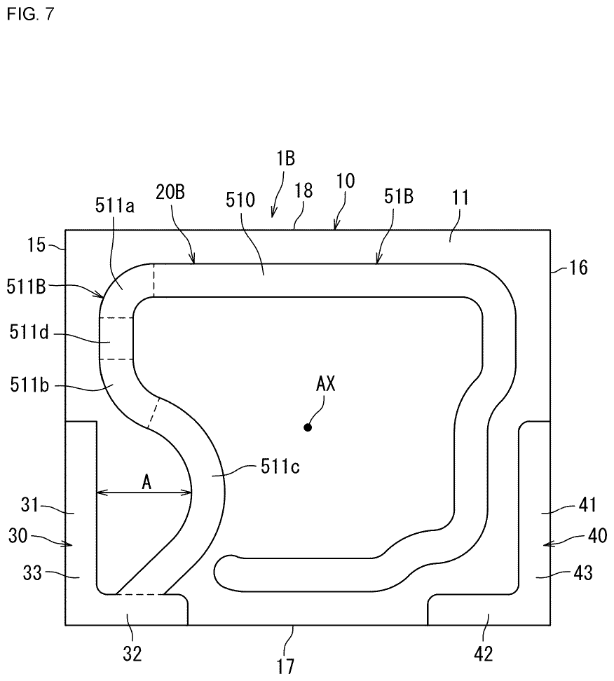

FIG. 7 is a front view illustrating a third embodiment of the inductor component when viewed in the axial direction of the first coil wiring layer. The third embodiment is different from the first embodiment in the shape of the connecting portion of the first coil wiring layer of the coil. This different configuration will be described below. Other configurations are the same as those of the first embodiment, and the reference numerals same as those of the first embodiment are given and the description thereof will be omitted.

As illustrated in FIG. 7, in a coil 20B of an inductor component 1B according to the third embodiment, a first coil wiring layer 511c of a third curved portion 51B is connected to the first bottom surface portion 32 of the first outer electrode 30 when viewed in the axis AX direction. The third curved portion 511c protrudes inward in the radial direction of the coil 20B. The third curved portion 511c corresponds to an example of a “second curved portion”. The first curved portion 511a, the second curved portion 511b, and the linear portion 511d of the first coil wiring layer 51B have the configuration similar to the first curved portion 511a, the second curved portion 511b, and the linear portion 511d of the first coil wiring layer 51 described in the first embodiment.

According to the above-described configuration, since the third curved portion 511c connected to the first bottom surface portion 32 protrudes inward in the radial direction of the coil 20B, the third curved portion 511c can be disposed away from the first end surface portion 31 as indicated by an arrow A. Thus, stray capacitance between the third curved portion 511c and the first end surface portion 31 can be suppressed.

In addition, since the third curved portion 511c can be disposed away from the first end surface portion 31, the space between the third curved portion 511c and the first end surface portion 31 is widened as indicated by the arrow A. As a result, when the coil wiring layer and the outer electrode are manufactured by a photolithography method, the flow of the developer is improved and the developability is improved.

Although not illustrated, preferably, similarly, when viewed in the axis AX direction, the third curved portion 521c (see FIG. 5) of the second coil wiring layer 52 is connected to the second bottom surface portion 42 of the second outer electrode 40. The third curved portion 521c protrudes inward in the radial direction of the coil.

According to the above-described configuration, since the third curved portion connected to the second bottom surface portion 42 protrudes inward in the radial direction of the coil, the third curved portion can be disposed away from the second end surface portion 41. Thus, stray capacitance between the third curved portion and the second end surface portion 41 can be suppressed.

In addition, since the third curved portion can be disposed away from the second end surface portion 41, the space between the third curved portion and the second end surface portion 41 is widened. As a result, when the coil wiring layer and the outer electrode are manufactured by a photolithography method, the flow of the developer is improved and the developability is improved.

### Fourth Embodiment

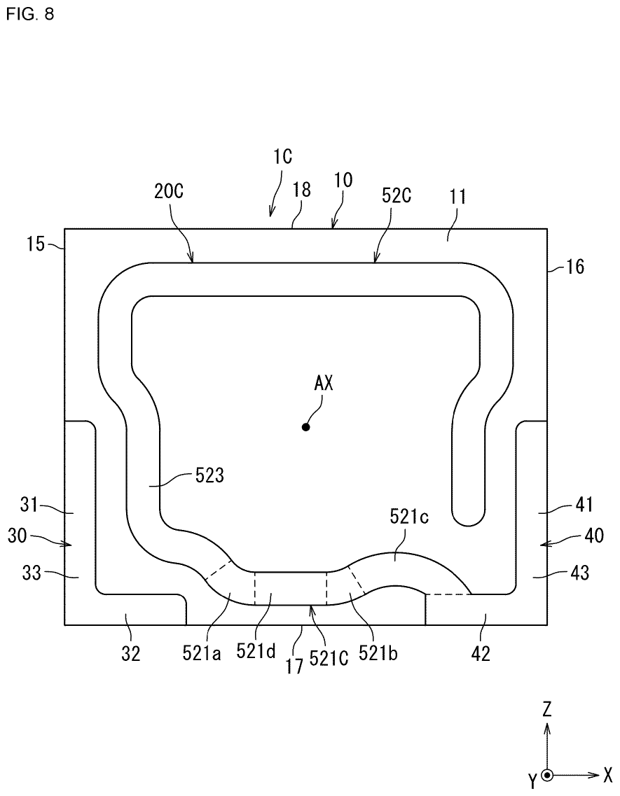

FIG. 8 is a front view illustrating a fourth embodiment of the inductor component when viewed in the axial direction of the second coil wiring layer. The fourth embodiment is different from the first embodiment in the shape of the second coil wiring layer of the coil. This different configuration will be described below. Other configurations are the same as those of the first embodiment, and the reference numerals same as those of the first embodiment are given and the description thereof will be omitted.

As illustrated in FIG. 8, in a coil 20C of an inductor component 1C of the fourth embodiment, a second coil wiring layer 52C is connected to the second outer electrode 40. When viewed in the axis AX direction, the second coil wiring layer 52C includes a first outer electrode opposing portion 523 opposed to the first outer electrode 30 and a connecting portion 521C connected between the second outer electrode 40 and the first outer electrode opposing portion 523. The connecting portion 521C is opposed to the bottom surface 17. The connecting portion 521C includes at least one curved portion 521a, 521b, or 521c.

According to the above-described configuration, since the connecting portion 521C includes the curved portions 521a, 521b, and 521c, even when thermal stress is applied to the inductor component 1C at the time of firing or mounting, the stress applied to the connecting portion 521C can be reduced. In addition, even when bending stress is applied to the inductor component 1C at the time of mounting, stress applied to the connecting portion 521C can be reduced. Thus, stress at the boundary portion between the connecting portion 521C and the second outer electrode 40 can be reduced. For example, the occurrence of cracks in the boundary portion between the connecting portion 521C and the second outer electrode 40 can be suppressed.

As illustrated in FIG. 8, when viewed in the axis AX direction, the connecting portion 521C includes, in order from the first outer electrode opposing portion 523 toward the second outer electrode 40, the first curved portion 521a protruding outward in the radial direction of the coil 20C, the linear portion 521d parallel to the bottom surface 17, the second curved portion 521b protruding outward in the radial direction of the coil 20C, and the third curved portion 521c protruding inward in the radial direction of the coil 20C. The first curved portion 521a is connected to the first outer electrode opposing portion 523. The third curved portion 521c is connected to the second bottom surface portion 42 of the second outer electrode 40. According to the above-described configuration, since the connecting portion 521C includes the first curved portion 521a, the second curved portion 521b, and the third curved portion 521c, even when thermal stress or bending stress is applied to the inductor component 1C at the time of mounting or the like, stress applied to the connecting portion 521C can be reduced. The number of the curved portions 521a, 521b, and 521c and the linear portions 521d may be increased or decreased.

Preferably, as in the first embodiment, the total length of the linear portions 521d is 40% or less of the total length of the curved portions 521a, 521b, and 521c. According to the above-described configuration, even when thermal stress or bending stress is applied to the inductor component 1C, stress applied to the connecting portion 521C can be further reduced because the ratio of the linear portion 521d is small. Thus, stress at the boundary portion between the connecting portion 521C and the second outer electrode 40 can be further reduced.

Although not illustrated, similarly, the first coil wiring layer connected to the first outer electrode 30 preferably includes a second outer electrode opposing portion opposed to the second outer electrode 40 and a connecting portion connected between the first outer electrode 30 and the second outer electrode opposing portion when viewed in the axis AX direction. The connecting portion is opposed to the bottom surface 17. The connecting portion includes at least one curved portion.

According to the above configuration, since the connecting portion includes the curved portion, even when thermal stress is applied to the inductor component at the time of firing or mounting, stress applied to the connecting portion can be reduced. In addition, even when bending stress is applied to the inductor component at the time of mounting, the stress applied to the connecting portion can be reduced. Thus, stress at the boundary portion between the connecting portion and the first outer electrode 30 can be reduced. For example, the occurrence of cracks in the boundary portion between the connecting portion and the first outer electrode 30 can be suppressed.

Note that the present disclosure is not limited to the above-described embodiments, and design changes can be made without departing from the scope of the present disclosure. For example, the features of the first to fourth embodiments may be combined in various ways. Further, the number of coil wiring layers may be increased or decreased, and the number of via wiring layers may be increased or decreased. The top surface portion and the connecting portion of the coil wiring layer may include a linear portion or may be formed in a curved shape.

In the above-described embodiments, each of the first outer electrode and the second outer electrode is an L-shaped electrode including an end surface portion and a bottom surface portion, but may be a bottom surface electrode including a bottom surface portion.

The present disclosure includes the following aspects.
[1] An inductor component comprising an element body; a coil provided in the element body and spirally wound along an axis; and a first outer electrode and a second outer electrode that are provided in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The axis is parallel to the bottom surface and intersects the first side surface and the second side surface. The coil includes a plurality of coil wiring layers laminated along the axis, and the plurality of coil wiring layers include a first coil wiring layer connected to the first outer electrode. When viewed in a direction of the axis, the first coil wiring layer includes a top surface portion opposed to the top surface and a connecting portion connected between the first outer electrode and the top surface portion, and the connecting portion includes at least one curved portion.
[2] An inductor component comprising an element body; a coil provided in the element body and spirally wound along an axis; and a first outer electrode and a second outer electrode that are provided in the element body and electrically connected to the coil. The element body includes a first end surface and a second end surface opposed to each other, a first side surface and a second side surface opposed to each other, a bottom surface connected between the first end surface and the second end surface and between the first side surface and the second side surface, and a top surface opposed to the bottom surface. The axis is parallel to the bottom surface and intersects the first side surface and the second side surface. The coil includes a plurality of coil wiring layers laminated along the axis, and the plurality of coil wiring layers include a second coil wiring layer connected to the second outer electrode. When viewed in a direction of the axis, the second coil wiring layer includes a first outer electrode opposing portion opposed to the first outer electrode, and a connecting portion connected between the second outer electrode and the first outer electrode opposing portion and opposed to the bottom surface, and the connecting portion includes at least one curved portion.
[3] The inductor component according to term [1] or [2], wherein, when viewed in the direction of the axis, the connecting portion includes a linear portion, and a total length of the linear portion is 40% or less of a total length of the curved portion.
[4] The inductor component according to term [1], wherein the at least one curved portion includes a first curved portion connected to the top surface portion when viewed in the direction of the axis, and the first curved portion protrudes outward in a radial direction of the coil.
[5] The inductor component according to term [1] or [2], wherein the connecting portion is formed in a curved shape when viewed in the direction of the axis.
[6] The inductor component according to term [5], wherein the connecting portion includes at least four curved portions, each of which being the at least one curved portion, when viewed in the axial direction.
[7] The inductor component according to term [1] or [4], wherein the first outer electrode includes a first end surface portion extending along the first end surface and a first bottom surface portion connected to the first end surface portion and extending along the bottom surface. When viewed in the direction of the axis, the at least one curved portion includes a second curved portion connected to the first bottom surface portion, and the second curved portion protrudes inward in a radial direction of the coil.
[8] The inductor component according to term [1], wherein, when viewed in the direction of the axis, the connecting portion includes a linear portion, and includes at least one curved portion between the linear portion and the first outer electrode.
[9] The inductor component according to term [8], wherein the linear portion is opposed to the first end surface.
[10] The inductor component according to term [9], wherein the at least one curved portion between the linear portion and the first outer electrode protrudes inward in a radial direction of the coil.
[11] The inductor component according to term [10], wherein the at least one curved portion between the linear portion and the first outer electrode is directly connected to the first outer electrode.

What is claimed is:

1. An inductor component comprising:
an element body including a first end surface and a second end surface opposed to each other, a first side surface and a second side surface opposed to each other, a bottom surface connected between the first end surface and the second end surface and between the first side surface and the second side surface, and a top surface opposed to the bottom surface;
a coil in the element body and spirally wound along an axis that is parallel to the bottom surface and intersects the first side surface and the second side surface; and
a first outer electrode and a second outer electrode that are in the element body and electrically connected to the coil,
wherein
the coil includes a plurality of coil wiring layers laminated along the axis, and the plurality of coil wiring layers include a first coil wiring layer connected to the first outer electrode, and
when viewed in a direction of the axis, the first coil wiring layer includes a top surface portion opposed to the top surface and a connecting portion connected between the first outer electrode and the top surface portion, and the connecting portion includes at least one curved portion.

2. An inductor component comprising:
an element body including a first end surface and a second end surface opposed to each other, a first side surface and a second side surface opposed to each other, a bottom surface connected between the first end surface and the second end surface and between the first side surface and the second side surface, and a top surface opposed to the bottom surface;
a coil in the element body and spirally wound along an axis that is parallel to the bottom surface and intersects the first side surface and the second side surface; and
a first outer electrode and a second outer electrode that are in the element body and electrically connected to the coil,
wherein
the coil includes a plurality of coil wiring layers laminated along the axis, and the plurality of coil wiring layers include a second coil wiring layer connected to the second outer electrode, and
when viewed in a direction of the axis, the second coil wiring layer includes a first outer electrode opposing portion opposed to the first outer electrode, and a connecting portion connected between the second outer electrode and the first outer electrode opposing portion and opposed to the bottom surface, and the connecting portion includes at least one curved portion.

3. The inductor component according to claim 1, wherein
when viewed in the direction of the axis, the connecting portion includes a linear portion, and a total length of the linear portion is 40% or less of a total length of the curved portion.

4. The inductor component according to claim 1, wherein
the at least one curved portion includes a first curved portion connected to the top surface portion when viewed in the direction of the axis, and the first curved portion protrudes outward in a radial direction of the coil.

5. The inductor component according to claim 1, wherein
the connecting portion has a curved shape when viewed in the direction of the axis.

6. The inductor component according to claim 5, wherein
the connecting portion includes at least four curved portions, each of which being the at least one curved portion, when viewed in the axial direction.

7. The inductor component according to claim 1, wherein
the first outer electrode includes a first end surface portion extending along the first end surface and a first bottom surface portion connected to the first end surface portion and extending along the bottom surface, and
when viewed in the direction of the axis, the at least one curved portion includes a second curved portion connected to the first bottom surface portion, and the second curved portion protrudes inward in a radial direction of the coil.

8. The inductor component according to claim 1, wherein
when viewed in the direction of the axis, the connecting portion includes a linear portion, and includes the at least one curved portion between the linear portion and the first outer electrode.

9. The inductor component according to claim 8, wherein
the linear portion is opposed to the first end surface.

10. The inductor component according to claim 9, wherein
the at least one curved portion between the linear portion and the first outer electrode protrudes inward in a radial direction of the coil.

11. The inductor component according to claim 10, wherein
the at least one curved portion between the linear portion and the first outer electrode is directly connected to the first outer electrode.

12. The inductor component according to claim 2, wherein
when viewed in the direction of the axis, the connecting portion includes a linear portion, and a total length of the linear portion is 40% or less of a total length of the curved portion.

13. The inductor component according to claim 2, wherein
the connecting portion has a curved shape when viewed in the direction of the axis.

14. The inductor component according to claim 13, wherein
the connecting portion includes at least four curved portions, each of which being the at least one curved portion, when viewed in the axial direction.

15. The inductor component according to claim 4, wherein
the first outer electrode includes a first end surface portion extending along the first end surface and a first bottom surface portion connected to the first end surface portion and extending along the bottom surface, and
when viewed in the direction of the axis, the at least one curved portion includes a second curved portion connected to the first bottom surface portion, and the second curved portion protrudes inward in a radial direction of the coil.
